(19) United States
(12) Patent Application Publication
(10) Pub. No.: US 2026/0227879 A1
(43) Pub. Date: Aug. 6, 2026

(54) SENSING DEVICE, DISPLAY DEVICE INCLUDING THE SAME, AND ELECTRONIC DEVICE

(71) Applicant: Samsung Display Co., Ltd., Yongin-Si (KR)

(72) Inventors: Jin Young JEON, Yongin-si (KR); Tae Seong KIM, Yongin-si (KR); Young Rok SONG, Yongin-si (KR); Seong Min CHAI, Yongin-si (KR)

(21) Appl. No.: 19/278,189

(22) Filed: Jul. 23, 2025

(30) Foreign Application Priority Data
Feb. 6, 2025 (KR) 10-2025-0015323

(51) Int. Cl. G06F 3/044; G06F 3/041

(52) U.S. Cl. CPC G06F 3/0446; G06F 3/04164; G06F 2203/04111; G06F 2203/04112

(57) ABSTRACT

A display device and an electronic device include a sensing device. The sensing device including a first sensor electrode extending in a first direction, and a second sensor electrode extending in a second direction and intersecting the first sensor electrode. Each of a first sensor pattern and a second sensor pattern of the second sensor electrode is not overlapping with the first sensor electrode, and a bridge pattern of the second sensor electrode partially overlaps with the first sensor electrode and connects the first sensor pattern and the second sensor pattern. The bridge pattern extends in a spiral form from a first end connected to the first sensor pattern to a second end connected to the second sensor pattern.

This application claims priority to Korean Patent Application No. 10-2025-0015323, filed on Feb. 6, 2025, and all the benefits accruing therefrom under 35 U.S.C. § 119, the content of which in its entirety is herein incorporated by reference.

### BACKGROUND

### 1. Field

An embodiment of the disclosure relates to a sensing device, a display device including the same, and an electronic device.

### 2. Description of the Related Art

A display device may include a display for displaying an image and a touch sensor for sensing an input (for example, a touch input) from an object. The touch sensor may measure coordinates of a point where the input from the object has occurred. In addition, the display device may further include a pressure sensor which detects the intensity of touch pressure.

### SUMMARY

An embodiment of the disclosure provides a sensing device capable of pressure sensing while be implemented in a thin-profile configuration, as well as a display device and an electronic device including the same.

According to an embodiment of the disclosure, a sensing device includes a first sensor electrode extending in a first direction, and a second sensor electrode extending in a second direction and intersecting the first sensor electrode. The second sensor electrode comprises a first sensor pattern and a second sensor pattern, each of the first sensor pattern and the second sensor pattern is not overlapping with the first sensor electrode, and a bridge pattern partially overlapping with the first sensor electrode and connecting the first sensor pattern and the second sensor pattern. The bridge pattern extends in a spiral form from a first end connected to the first sensor pattern to a second end connected to the second sensor pattern.

In an embodiment, the bridge pattern may have a double spiral structure.

In an embodiment, the bridge pattern may have a single spiral structure.

In an embodiment, the first sensor electrode, the first sensor pattern, and the second sensor pattern may be disposed in a first conductive layer, the bridge pattern may be disposed in a second conductive layer, and an insulating layer may be disposed between the first conductive layer and the second conductive layer.

In an embodiment, each of the first sensor electrode and the second sensor electrode may include mesh lines. The mesh lines may form a mesh hole in each of the first sensor electrode and the second sensor electrode, and the mesh hole may not be formed in the bridge pattern.

In an embodiment, the first sensor electrode and the second sensor electrode may sense a touch input based on a change in capacitance, and the bridge pattern may have a resistance varying in response to pressure applied to the bridge pattern and sense the pressure.

In an embodiment, the sensing device may further include a first sensing line connected to the first sensor electrode, a second sensing line connected to the second sensor electrode, and a third sensing line connected to the bridge pattern The bridge pattern may include a first portion and a second portion separated with respect to a node connected to the third sensing line.

In an embodiment, at least one of the first portion and the second portion may have a U-shape in a plan view.

In an embodiment, the bridge pattern and the first sensor pattern may include a same material.

In an embodiment, the bridge pattern and the first sensor pattern may include different materials from each other.

According to an embodiment of the disclosure, a display device may include a light-emitting element arranged on a base layer, an encapsulation layer arranged on the light-emitting element, and a sensor arranged on the encapsulation layer. The sensor comprises a first sensor electrode extending in a first direction, and a second sensor electrode extending in a second direction and intersecting the first sensor electrode. The second sensor electrode comprises a first sensor pattern and a second sensor pattern, each of the first sensor pattern and the second sensor pattern is not overlapping with the first sensor electrode, and a bridge pattern partially overlapping with the first sensor electrode and connecting the first sensor pattern and the second sensor pattern. The bridge pattern extends in a spiral form from a first end connected to the first sensor pattern to a second end connected to the second sensor pattern.

In an embodiment, the first sensor electrode, the first sensor pattern, and the second sensor pattern may be disposed in a first conductive layer, the bridge pattern may be disposed in a second conductive layer, and an insulating layer may be disposed between the first conductive layer and the second conductive layer.

In an embodiment, each of the first sensor electrode and the second sensor electrode may include mesh lines, and the mesh lines may form a mesh hole in each of the first sensor electrode and the second sensor electrode. The mesh hole may correspond to a light-emitting region of the light-emitting element, and the mesh hole may not be formed in the bridge pattern.

In an embodiment, the first sensor electrode and the second sensor electrode may sense a touch input based on a change in capacitance, and the bridge pattern may have a resistance varying in response to pressure applied to the bridge pattern and sense the pressure.

In an embodiment, the sensor may include a first sensing line connected to the first sensor electrode, a second sensing line connected to the second sensor electrode, and a third sensing line connected to the bridge pattern. The bridge pattern may include a first portion and a second portion separated with respect to a node connected to the third sensing line.

According to an embodiment of the disclosure, an electronic device may include a processor providing input image data, a display module displaying an image based on the input image data, and a power supply supplying power to the display module. The display module comprises a display panel including pixels, and a sensor arranged on the display panel and sensing a touch input to the display module. The sensor comprises a first sensor electrode extending in a first direction, and a second sensor electrode extending in a second direction and intersecting the first sensor electrode. The second sensor electrode comprises a first sensor pattern and a second sensor pattern, each of the first sensor pattern and the second sensor pattern is not overlapping with the first sensor electrode, and a bridge pattern partially overlapping with the first sensor electrode and connecting the first sensor pattern and the second sensor pattern. The bridge pattern extends in a spiral form from a first end connected to the first sensor pattern to a second end connected to the second sensor pattern. The processor detects the touch input based on a change in capacitance, and detects a pressure of the touch input based upon a change in resistance of the bridge pattern in response to the pressure applied to the bridge pattern.

In an embodiment, the first sensor electrode, the first sensor pattern, and the second sensor pattern may be disposed in a first conductive layer, the bridge pattern may be disposed in a second conductive layer, and an insulating layer may be disposed between the first conductive layer and the second conductive layer.

In an embodiment, each of the first sensor electrode and the second sensor electrode may include mesh lines, and the mesh lines may for a mesh hole in each of the first sensor electrode and the second sensor electrode. The mesh hole may correspond to a light-emitting region of each of the pixels, and the mesh hole may not be formed in the bridge pattern.

In an embodiment, the sensor may include a first sensing line connected to the first sensor electrode, a second sensing line connected to the second sensor electrode, and a third sensing line connected to the bridge pattern. The bridge pattern may include a first portion and a second portion separated with respect to a node connected to the third sensing line.

In an embodiment, the processor may detect the pressure based on a signal output through the third sensing line.

### BRIEF DESCRIPTION OF THE DRAWINGS

The above and other features of the disclosure will become more apparent by describing in further detail embodiments thereof with reference to the accompanying drawings.

FIG. 1 is a diagram illustrating a display device according to an embodiment.

FIG. 2 is a cross-sectional view showing a display device of FIG. 1.

FIG. 3 is a block diagram illustrating a display panel and a display panel driver included in a display device of FIG. 1.

FIG. 4 is a block diagram illustrating a touch panel included in a display device of FIG. 1.

FIG. 5 is a cross-sectional view showing a display device of FIG. 1.

FIGS. 6 and 7 are enlarged plan views of an area AA of FIG. 4.

FIG. 8 is a diagram illustrating a first conductive layer in an area AA of FIG. 4.

FIG. 9 is a diagram illustrating a second conductive layer in an area AA of FIG. 4.

FIG. 10 is a cross-sectional view taken along a second bridge pattern of FIG. 8.

FIG. 11 is a diagram illustrating a touch panel driver included in a display device of FIG. 1.

FIGS. 12, 13, and 14 are enlarged plan views of an area AA of FIG. 4.

FIG. 15 is a block diagram of an electronic device 10 according to an embodiment.

FIG. 16 shows schematic views of various embodiments of an electronic device.

### DETAILED DESCRIPTION OF THE EMBODIMENT

The disclosure may be implemented in various different forms. Therefore, it should be noted that the disclosure is not limited to specific embodiments illustrated in the drawings and described in the specification, and the disclosure includes all modifications, equivalents, and substitutions within the spirit and technical scope of the disclosure.

Terms, such as “first”, “second”, or the like, may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expression may include plural forms unless the context clearly dictates otherwise.

It should be understood that in the disclosure, a term, such as “include”, “have”, or the like, is used to explain the presence of a feature, a number, a step, an operation, a component, a part, or a combination thereof described in the specification, but does not exclude a possibility of the presence or addition of one or more other features, numbers, steps, operations, components, parts, or combinations thereof. Furthermore, in case that a first part such as a layer, a film, a region, or a plate is disposed “on” a second part, the first part may be not only “directly on” the second part but also “indirectly on” the second part, for example, a third part may be disposed between the first part and the second part. In addition, when it is expressed that a first part such as a layer, a film, a region, or a plate is formed on a second part, the surface of the second part on which the first part is formed is not necessarily limited to an upper surface of the second part but may include other surfaces such as a side surface or a lower surface of the second part. To the contrary, in case that a first part such as a layer, a film, a region, or a plate is “under” a second part, the first part may be not only “directly under” the second part but a third part may intervene between them.

Advantages and features of the disclosure and methods for achieving them will be made clear from embodiments described below in detail with reference to the accompanying drawings. However, they may be implemented in different forms and should not be construed as limited to the embodiments set forth herein. Rather, these embodiments are provided to fully convey the scope of the disclosure to those skilled in the art. It will be understood that when an element is referred to as being “coupled” or “connected” to a certain element, it may be directly coupled or connected to the certain element or may be indirectly coupled or connected to the certain element, with intervening elements being present therebetween.

Hereinafter, a display device according to an embodiment of the present disclosure is described with reference to drawings related to embodiments of the disclosure.

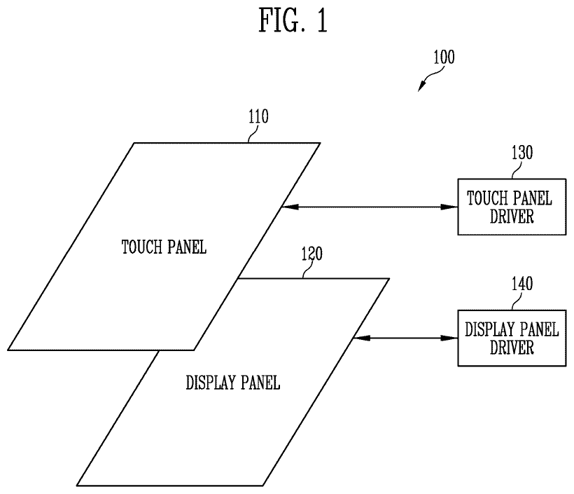

FIG. 1 is a diagram illustrating a display device 100 according to an embodiment.

Referring to FIG. 1, the display device 100 includes a touch panel 110 (or a sensing panel or a sensor), a display panel 120, a touch panel driver 130 (or a first driver), and a display panel driver 140 (or a second driver). The touch panel 110 and the touch panel driver 130 may form a sensing device.

The touch panel 110 may sense an external input such as touch, pressure, fingerprint, hovering, proximity, or motion. For example, the touch panel 110 may include sensor electrodes. In an embodiment (e.g., in a mutual capacitance scheme), the sensor electrodes may include driving electrodes and sensing electrodes. In an embodiment (e.g., in a self-capacitance scheme), the sensor electrodes may include one type of sensors.

The display panel 120 displays an image. For example, the display panel 120 may be a self-luminous display panel such as an organic light emitting display panel. The display panel 120 may include an organic light emitting diode, an inorganic light emitting diode, a quantum dot/well light emitting diode, or the like. However, the disclosure is not limited thereto. For example, the display panel 120 may be a non-light emitting type display panel such as a liquid crystal display panel. When the display panel 120 is implemented in a non-light emitting type, the display device 100 may additionally include a light source such as a back-light unit.

In FIG. 1, the touch panel 110 and the display panel 120 are shown separately from each other. However, this is only for functionally distinguishing the touch panel 110 from the display panel 120 in the display device 100. For example, the touch panel 110 and the display panel 120 may be formed by separate processes and coupled to each other (for example, the touch panel 110 and the display panel 120 may be coupled to each other by attaching the touch panel 110 to a first surface of the display panel 120). That is, the touch panel 110 may be formed in an add-on type. However, the disclosure is not limited thereto. For example, the touch panel 110 and the display panel 120 may be formed by a single process (for example, a process of manufacturing the display panel 120). That is, the touch panel 110 may be formed in an in-cell type.

The touch panel 110 may be provided on a first surface of the display panel 120. For example, the touch panel 110 may be provided on the first surface (e.g., an upper surface) of the display panel 120 in a direction in which an image is displayed. For example, the touch panel 110 may be formed directly on at least one surface of the display panel 120, or may be formed inside the display panel 120. For example, the touch panel 110 may be formed directly on an outer surface of an upper substrate or a lower substrate of the display panel 120 (i.e., an upper surface of the upper substrate or a lower surface of the lower substrate), or may be directly formed on an inner surface of the upper substrate (i.e., a lower surface of the upper substrate) or an inner surface of the lower substrate (i.e., an upper surface of the lower substrate).

The touch panel driver 130 is electrically connected to the touch panel 110 to drive the touch panel 110. For example, the touch panel driver 130 may provide a driving signal to the sensor electrodes and receive a sensing signal from the sensor electrodes.

The display panel driver 140 may be electrically connected to the display panel 120 to drive the display panel 120. For example, the display panel driver 140 may provide a data signal to the display panel 120.

In an embodiment, each of the touch panel driver 130 and the display panel driver 140 may be an integrated circuit (IC). In an embodiment, at least a portion of the touch panel driver 130 and a portion of the display panel driver 140 may be integrated together within a single IC (or a processor).

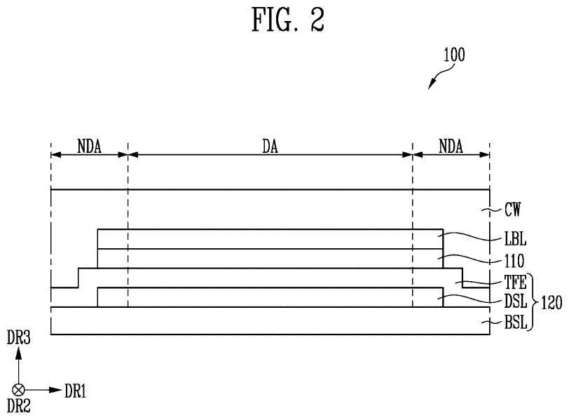

FIG. 2 is a cross-sectional view showing a display device 100 of FIG. 1.

Referring to FIG. 2, the touch panel 110 may be arranged on the display panel 120, and a cover window CW may be provided over the touch panel 110.

The display panel 120 may include a substrate BSL, a device layer DSL, and an encapsulation layer TFE. A light-blocking layer LBL may be disposed between the cover window CW and the touch panel 110.

The substrate BSL (or a base layer) may support the device layer DSL. The substrate BSL may include an insulating material. For example, the insulating material may include at least one of glass, quartz, ceramic, and plastic. According to an embodiment, the substrate BSL may be either a rigid substrate or a flexible substrate.

The device layer DSL may be arranged on the substrate BSL. The device layer DSL may include a pixel (or a sub-pixel) and a signal line. The pixel may include a light emitting element, a transistor, and a capacitor. The signal line may include a gate line configured to transmit a gate signal to each pixel and a data line configured to transmit a data voltage to each pixel. The pixel included in the device layer DSL may be located in a display area DA.

The encapsulation layer TFE may be provided on the device layer DSL. The encapsulation layer TFE may protect the device layer DSL from external moisture or oxygen. The encapsulation layer TFE may include two or more insulating layers formed on the device layer DSL. For example, the encapsulation layer TFE may include a first inorganic layer formed on the device layer DSL, an organic layer formed on the first inorganic layer, and a second inorganic layer arranged on the organic layer. For example, the encapsulation layer TFE may include a glass substrate to cover the device layer DSL. The encapsulation layer TFE may cover the device layer DSL in the display area DA and a non-display area NDA.

The touch panel 110 may be provided on the encapsulation layer TFE. In an embodiment, the touch panel 110 may be formed directly on the encapsulation layer TFE. In an embodiment, the touch panel 110 may be formed separately from the display panel 120 and arranged on (e.g., attached to) the encapsulation layer TFE. The touch panel 110 may have a sensor area in at least a part of an overlapping area with the display area DA.

The light-blocking layer LBL may include a color filter and a light blocking member. Depending on the embodiment, the light-blocking layer LBL may be omitted.

The cover window CW may be provided over the touch panel 110. The cover window CW may protect the display panel 120 and the touch panel 110 from external impact or the like. The cover window CW may be implemented using a light-transmissive (e.g., transparent) material, such as glass or plastic film.

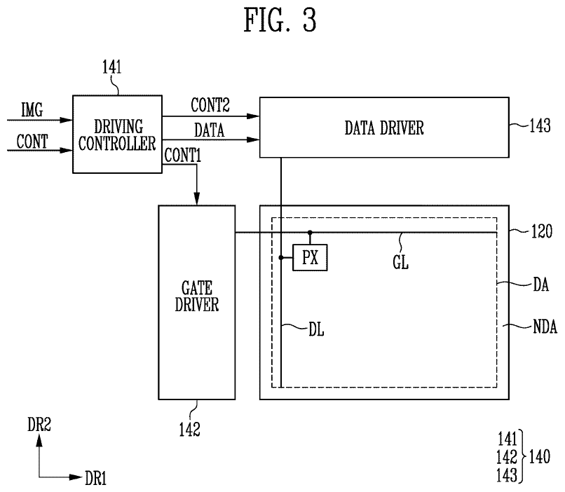

FIG. 3 is a block diagram illustrating a display panel 120 and a display panel driver 140 included in a display device 100 of FIG. 1.

Referring to FIG. 3, the display panel 120 may include the display area DA which displays an image, and the non-display area NDA arranged adjacent to the display area DA.

The display panel 120 may include a gate line GL, a data line DL, and a pixel PX. The pixel PX may be electrically connected to the gate line GL and the data line DL. The gate line GL may extend in a first direction DR1, and the data line DL may extend in a second direction DR2 intersecting the first direction DR1.

The display panel driver 140 may include a driving controller 141, a gate driver 142, and a data driver 143. In an embodiment, the driving controller 141 and the data driver 143 may be integrated into a single chip. In an embodiment, the gate driver 142 may be mounted on the non-display area NDA of the display panel 120.

The driving controller 141 may receive input image data IMG and an input control signal CONT from a main processor (e.g., a graphics processing unit (GPU) or the like). For example, the input image data IMG may include red image data, green image data, and blue image data. For example, the input control signal CONT may include a master clock signal and a data enable signal. The input control signal CONT may further include a vertical synchronization signal and a horizontal synchronization signal.

The driving controller 141 may generate a first control signal CONT1, a second control signal CONT2, and a data signal DATA based on the input image data IMG and the input control signal CONT. For example, the first control signal CONT1 may include a vertical start signal and a gate clock signal, and the second control signal CONT2 may include a horizontal start signal and a load signal.

The gate driver 142 may generate a gate signal in response to the first control signal CONT1. The gate driver 142 may output a gate signal to the gate line GL.

In response to the second control signal CONT2, the data driver 143 may convert the data signal DATA into a voltage in analog form to generate a data voltage. The data driver 143 may output the data voltage to the data line DL.

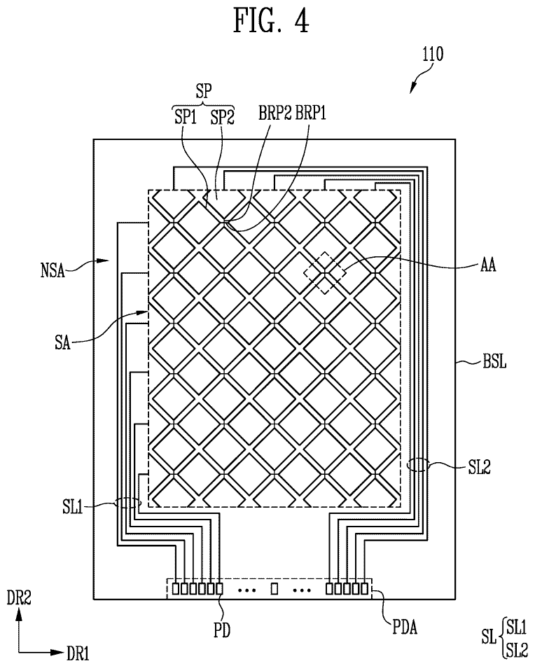

FIG. 4 is a block diagram illustrating a touch panel 110 included in a display device 100 of FIG. 1.

Referring to FIG. 4, the touch panel 110 (or the substrate BSL) may include a sensor area SA (or a sensing area or an active area) which detects a touch input, and a non-sensor area NSA (or a non-sensing area) surrounding at least a portion of the sensor area SA.

The sensor area SA may be arranged in a central region of the substrate BSL so as to overlap with the display area DA (see FIGS. 2 and 3). The sensor area SA may have substantially the same shape as the display area DA, but the present disclosure is not limited thereto. The sensor area SA may include a sensor electrode for sensing a touch input.

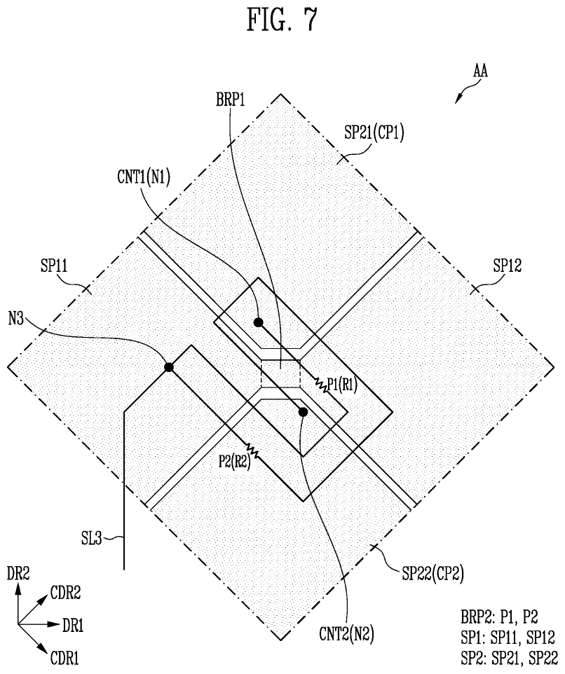

The non-sensor area NSA may be arranged in a peripheral region of the substrate BSL so as to overlap with the non-display area NDA (see FIGS. 2 and 3). The peripheral region may surround the central region of the substrate BSL. The non-sensor area NSA may include a sensing line SL electrically connected to the sensor electrode to receive and transmit a sensing signal. In addition, the non-sensor area NSA may include a pad portion PDA connected to the sensing line SL and electrically connected to the sensor electrode of the sensor area SA. The pad portion PDA may include a pad PD. The sensing line SL may include a plurality of first sensing lines SL1 and a plurality of second sensing lines SL2. According to an embodiment, the sensing line SL may further include a third sensing line SL3 (see FIG. 7).

The sensor electrode SP may include a plurality of first sensor electrodes SP1, and a plurality of second sensor electrodes SP2 electrically insulated from the first sensor electrodes SP1. In addition, the sensor electrode SP may further include first and second bridge patterns BRP1 and BRP2.

The first sensor electrodes SP1 may be arranged in the first direction DR1 and be electrically connected to adjacent first sensor electrodes SP1 through the first bridge patterns BRP1, thereby forming at least one sensor row. The second sensor electrodes SP2 may be arranged in the second direction DR2 which intersects the first direction DR1, and may be electrically connected to adjacent second sensor electrodes SP2 through the second bridge patterns BRP2, thereby forming at least one sensor column.

Each of the first and second sensor electrodes SP1 and SP2 may be electrically connected to a pad PD through corresponding sensing lines SL. In an example, the first sensor electrodes SP1 may be electrically connected to a first pad PD through the respective first sensing lines SL1, and the second sensor electrodes SP2 may be electrically connected to a second pad PD through the respective second sensing lines SL2.

The first sensor electrodes SP1 may be driving electrodes which receive a driving signal for detecting a touch position in the sensor area SA from the touch panel driver 130, and the second sensor electrodes SP2 may be sensing electrodes which output a sensing signal for detecting a touch position in the sensor area SA to the touch panel driver 130. However, the present disclosure is not limited thereto, and the first sensor electrodes SP1 may be sensing electrodes, and the second sensor electrodes SP2 may be driving electrodes.

The touch panel 110 may recognize a user's touch by sensing a change in mutual capacitance formed between the first and second sensor electrodes SP1 and SP2.

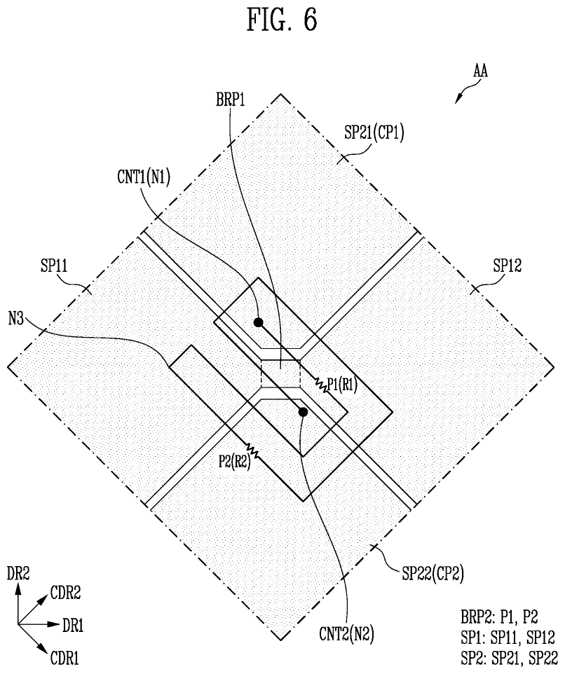

In an embodiment, the touch panel 110 may sense the pressure caused by the user's touch by sensing the amount of change in resistance of the second bridge patterns BRP2. The specific configuration of the second bridge patterns BRP2 for sensing the pressure will be described below with reference to FIG. 6.

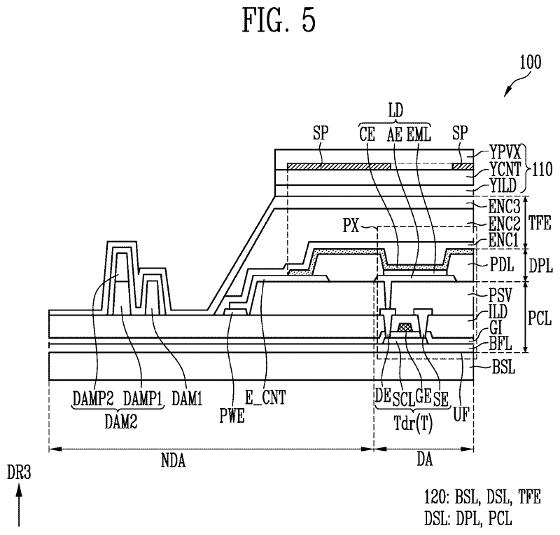

FIG. 5 is a cross-sectional view showing a display device 100 of FIG. 1. FIG. 5 shows a cross section of the display device 100 taken along one side of the display device.

Referring to FIG. 5, the display device 100 may include the pixel PX and the sensor electrode SP in the display area DA. Hereinafter, a stacked structure of the display device 100 in the display area DA will be described first, and then the stacked structure of the display device 100 in the non-display area NDA will be described.

The display device 100 may include a pixel circuit layer PCL, a display element layer DPL, the encapsulation layer TFE, and the touch panel 110 which are sequentially stacked on the substrate BSL. In the display area DA, the pixel circuit layer PCL may include a buffer layer BFL, a driving transistor Tdr, and a passivation layer PSV. The driving transistor Tdr controls the driving current provided to a light-emitting element LD. Since transistors T included in the pixel PX have substantially the same or similar structures to each other, only the driving transistor Tdr is shown in FIG. 5 for the convenience of the explanation.

The buffer layer BFL may be disposed on the substrate BSL. The buffer layer BFL may prevent diffusion of impurities into the driving transistor Tdr. The buffer layer BFL may be an insulating film and include an inorganic material. For example, the buffer layer BFL may include silicon nitride (SiNₓ), silicon oxide (SiOₓ), or silicon oxynitride (SiON), or may include a metal oxide such as aluminum oxide (AlOₓ). The buffer layer BFL may be omitted depending on the material and process conditions of the substrate BSL.

The driving transistor Tdr may be disposed on the buffer layer BFL (or the substrate BSL). The driving transistor Tdr may include a semiconductor pattern SCL, a gate electrode GE, a first terminal SE, and a second terminal DE. The first terminal SE may be one of a source electrode and a drain electrode, and the second terminal DE may be the other electrode. For example, when the first terminal SE is a source electrode, the second terminal DE may be a drain electrode.

The semiconductor pattern SCL may be disposed on the buffer layer BFL. The semiconductor pattern SCL may include a first contact region contacting the first terminal SE and a second contact region contacting the second terminal DE. A region located between the first contact region and the second contact region and overlapping with the gate electrode GE may be a channel region of the driving transistor Tdr. The semiconductor pattern SCL may include polysilicon, amorphous silicon, oxide semiconductor, or the like. The channel region may be a semiconductor pattern which is not doped with impurities, and may include an intrinsic semiconductor. The first contact region and the second contact region may be impurity-doped semiconductor patterns.

A gate insulating layer GI may be disposed on the semiconductor pattern SCL. The gate insulating layer GI may be an insulating film and include an inorganic material. However, the present disclosure is not limited thereto. For example, the gate insulating layer GI may include an organic material.

The gate electrode GE may be disposed on the semiconductor pattern SCL with the gate insulating layer GI interposed therebetween. The gate electrode GE may include a conductive material. For example, the conductive material may include a metal such as gold (Au), silver (Ag), aluminum (Al), molybdenum (Mo), chromium (Cr), titanium (Ti), nickel (Ni), neodymium (Nd), or copper (Cu).

An interlayer insulating layer ILD may be disposed on the gate electrode GE. The interlayer insulating layer ILD is an insulating layer, and may include an inorganic material. The interlayer insulating layer ILD may include a single layer or multiple layers. According to an embodiment, the interlayer insulating layer ILD may include an organic material.

The first terminal SE and the second terminal DE may be in contact with the first contact region and the second contact region of the semiconductor pattern SCL, respectively, through a contact hole extending through the interlayer insulating layer ILD and the gate insulating layer GI. The first and second terminals SE and DE may include a conductive material. Each of the first and second terminals SE and DE may include a single layer or multiple layers.

The passivation layer PSV may be disposed on the driving transistor Tdr.

The passivation layer PSV may be an insulating film. The passivation layer PSV may include an organic film or an inorganic film, or may include an organic film arranged on an inorganic film. The inorganic film may include an inorganic material. The organic film may include an organic material. For example, the organic material may include polyacrylate resin, epoxy resin, phenolic resin, polyamide resin, polyimide resin, unsaturated polyester resin, polyphenylene ether resin, polyphenylene sulfide resin, and benzocyclobutene resin.

The display element layer DPL may include the light-emitting element LD which is disposed on the passivation layer PSV and emits light. The light-emitting element LD may include first and second electrodes AE and CE and a light-emitting layer EML provided between the first and second electrodes. One of the first and second electrodes AE and CE may be an anode electrode, and the other electrode may be a cathode electrode. For example, the first electrode AE may be an anode electrode and the second electrode CE may be a cathode electrode. When the light-emitting element LD is a front-emitting organic light-emitting diode, the first electrode AE may be a reflective electrode and the second electrode CE may be a transmissive electrode.

The first electrode AE may be electrically connected to the second terminal DE of the driving transistor Tdr through a contact hole extending through the passivation layer PSV. The first electrode AE may include a reflective layer capable of reflecting light, or may further include a transparent conductive layer arranged over or under the reflective layer. For example, the transparent conductive layer may include a transparent conductive material. The transparent conductive material may include indium tin oxide (ITO), indium zinc oxide (IZO), indium gallium zinc oxide (IGZO), or indium tin zinc oxide (ITZO), or may include a conductive polymer such as PEDOT. The reflective layer may include a metallic material such as silver (Ag).

The display element layer DPL may further include a pixel defining layer PDL having an opening which extends to a part of the first electrode AE, for example, an upper surface of the first electrode AE. The pixel defining layer PDL may be an insulating layer and include an organic material.

The light-emitting layer EML may be disposed in a region corresponding to the opening of the pixel defining layer PDL. That is, the light-emitting layer EML may be disposed on a portion of a surface of the exposed first electrode AE. The light-emitting layer EML may have a multilayer thin-film structure including at least a light generation layer. The light-emitting layer EML may include a hole injection layer, a hole transport layer, the light generation layer, a hole blocking layer, an electron transport layer, and an electron injection layer.

The second electrode CE may be disposed on the light-emitting layer EML. The second electrode CE may be a common layer which is commonly formed on the plurality of pixels PX in the display area DA. The second electrode CE may be a transmissive electrode and include a transparent conductive material.

The encapsulation layer TFE may be disposed on the second electrode CE.

The encapsulation layer TFE may include first, second, and third encapsulation layers ENC1, ENC2, and ENC3. The first encapsulation layer ENC1 may be disposed on the display element layer DPL and cover at least a part of the display area DA and the non-display area NDA. The second encapsulation layer ENC2 may be disposed on the first encapsulation layer ENC1 and cover at least a part of the display area DA and the non-display area NDA. The third encapsulation layer ENC3 may be disposed on the second encapsulation layer ENC2 and cover at least a part of the display area DA and the non-display area NDA. The first and third encapsulation layers ENC1 and ENC3 may include an inorganic film including an inorganic material, and the second encapsulation layer ENC2 may include an organic film including an organic material.

The light-emitting element LD of the display element layer DPL shown in FIG. 5 may include an organic light-emitting diode having a first electrode AE, the light-emitting layer EML, and a second electrode CE, but the present disclosure is not limited thereto. For example, the light-emitting element LD of the display element layer DPL may include an inorganic light-emitting element in which a nitride-based semiconductor is grown.

The touch panel 110 may be disposed on the encapsulation layer TFE. The touch panel 110 may be provided directly on the encapsulation layer TFE using the encapsulation layer TEF as a base layer. In other words, the touch panel 110 may be directly formed on the encapsulation layer TFE through a process which is continuous with the process of forming the encapsulation layer TEF.

The touch panel 110 may include insulating layers sequentially stacked on the encapsulation layer TFE, that is, a first insulating layer YILD, a second insulating layer YCNT, and a third insulating layer YPVX. The touch panel 110 may also include the sensor electrode SP arranged between the insulating layers.

The first insulating layer YILD may include, but is not limited to, an inorganic material as a buffer layer. The first insulating layer YILD may be omitted depending on an embodiment.

The second insulating layer YCNT may be disposed on the first insulating layer YILD, or on the encapsulation layer TFE. The second insulating layer YCNT may be an insulating layer and may include, but is not limited to, an inorganic material.

The sensor electrode SP may be disposed on the second insulating layer YCNT. The sensor electrode SP may be arranged on the light-emitting element LD (or the pixel PX) and may not overlap with the light-emitting element LD in a third direction DR3. For example, the sensor electrode SP may have a mesh structure including a plurality of conductive fine lines (or mesh lines), and may include an opening (or a mesh hole) corresponding to the light-emitting element LD.

The sensor electrode SP may overlap with the second electrode CE. Interference of a lower configuration (and a signal applied thereto) of the second electrode CE with the sensor electrode SP, i.e., noise due to the lower configuration, may be prevented.

The non-display area NDA may include a power supply electrode PWE which receives a driving power supply (for example, a constant voltage) from the outside, and a connection electrode E_CNT connected to the power supply electrode PWE. The connection electrode E_CNT may electrically connect the power supply electrode PWE to the second electrode CE of the light-emitting element LD as shown in FIG. 5. The connection electrode E_CNT may be formed by the same process as the first electrode AE and include the same material as a first electrode AE1.

Dams DAM1 and DAM2 may be provided at the edge of the display device 100. For example, the dams DAM1 and DAM2 may be provided along the edge of the display device 100 in a plan view. A second dam portion DAM2 may be arranged outside of a first dam portion DAM1. The first dam portion DAM1 may be formed at the same time as the passivation layer PSV included in the pixel circuit layer PCL. The second dam portion DAM2 may include a lower portion DAMP1 formed simultaneously with the passivation layer PSV included in the pixel circuit layer PCL and an upper portion DAMP2 formed simultaneously with the pixel defining layer PDL included in the display element layer DPL. According to an embodiment, the dams DAM1 and DAM2 may be formed simultaneously with at least one or more of the insulating layers included in the pixel circuit layer PCL. The dams DAM1 and DAM2 may prevent an organic material in a liquid state from overflowing into the peripheral region of the substrate BSL during the process of forming the organic layer included in the encapsulation layer TFE, for example, the second encapsulation layer ENC2.

FIGS. 6 and 7 are enlarged plan views of an area AA of FIG. 4. FIGS. 6 and 7 show one intersection region where the first sensor electrode SP1 and the second sensor electrode SP2 intersect. The embodiments of FIGS. 6 and 7 may also be applied to other intersection regions.

Referring to FIGS. 6 and 7, the first sensor electrode SP1 may extend in the first direction DR1. The first sensor electrode SP1 may include an 11th sensor electrode SP11, a 12th sensor electrode SP12, and the first bridge pattern BRP1. The first bridge pattern BRP1 may connect the 11th sensor electrode SP11 and the 12th sensor electrode SP12.

The second sensor electrode SP2 may extend in the second direction DR2 and intersect the first sensor electrode SP1. The second sensor electrode SP2 may include a 21st sensor electrode SP21 (or a first sensor pattern CP1, a first segment, a first cell, and a first region), a 22nd sensor electrode SP22 (or a second sensor pattern CP2, a second segment, a second cell, and a second region), and the second bridge pattern BRP2. The 21st sensor electrode SP21 and the 22nd sensor electrode SP22 may not overlap with the first sensor electrode SP1, and may be distinguished from each other with respect to the first sensor electrode SP1. The second bridge pattern BRP2 may connect the 21st sensor electrode SP21 and the 22nd sensor electrode SP22 while partially overlapping with the first sensor electrode SP1. For example, the second bridge pattern BRP2 may be connected to the 21st sensor electrode SP21 through a first contact hole CNT1, and connected to the 22nd sensor electrode SP22 through a second contact hole CNT2.

According to an embodiment, the second bridge pattern BRP2 (or a bridge pattern) may extend in a spiral form with at least one winding (or coiled up) from a first end coupled (or connected) to the 21st sensor electrode SP21 to a second end coupled to the 22nd sensor electrode SP22. The first end may correspond to the first contact hole CNT1, and the second end may correspond to the second contact hole CNT2.

For example, a second bridge pattern BPR2 may include a first portion P1 and a second portion P2, which are distinguished with respect to a third node N3. As shown in FIG. 7, the third node N3 may be connected to a third sensing line SL3, but the present disclosure is not limited thereto. An arbitrary point of the second bridge pattern BPR2 may be the third node N3, and the position of the third node N3 may vary according to the design requirements of a first resistor R1 and a second resistor R2.

For example, the first portion P1 of the second bridge pattern BRP2 may extend spirally by sequentially changing directions from the first contact hole CNT1 in a first diagonal direction CDR1, then in a direction opposite to a second diagonal direction CDR2, and then in a direction opposite the first diagonal direction CDR1. The first diagonal direction CDR1 and the second diagonal direction CDR2 may intersect the first direction DR1 and the second direction DR2, respectively, and the second diagonal direction CDR2 may intersect the first diagonal direction CDR1. For example, the second portion P2 of the second bridge pattern BRP2 may extend spirally by sequentially changing directions from the third node N3 in the first diagonal direction CDR1, then in the second diagonal direction CDR2, then in the direction opposite to the first diagonal direction CDR1, then in the direction opposite to the second diagonal direction CDR2, and then in the first diagonal direction CDR1. At least a portion of each of the first portion P1 and the second portion P2 may have a U-shape, but the present disclosure is not limited thereto.

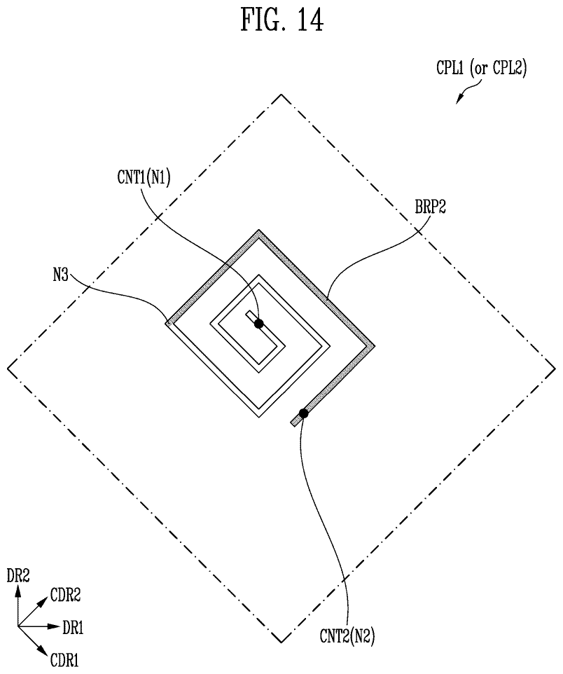

According to an embodiment, the second bridge pattern BRP2 may have a double spiral structure. For example, as shown in FIG. 6, the first portion P1 may rotate clockwise to extend from the first contact hole CNT1, and the second portion P2 may rotate counterclockwise to extend from the second contact hole CNT2. However, the shape of the second bridge pattern BRP2 is not limited thereto, and for example, the second bridge pattern BRP2 may have a single spiral structure (see FIG. 14).

As will be described below with reference to FIG. 11, the second bridge pattern BRP2 may correspond to a part of a Wheatstone bridge circuit. For example, each of the first resistor R1 of the first portion P1 and the second resistor R2 of the second portion P2 may correspond to a first resistor R1 and a second resistor R2, respectively, included in the Wheatstone bridge circuit. A resistance value of the second bridge pattern BRP2 (or a resistance of the first resistor R1 or a resistance of the second resistor R2) may change depending on the intensity of the touch, and a voltage of the third node N3 may change. The touch panel driver 130 (see FIG. 1) may detect the intensity of the touch or the pressure of the touch based on a change in voltage of the third node N3.

That is, the touch panel 110 of the disclosure includes the first sensor electrode SP1 and the second sensor electrode SP2 capable of sensing a touch input based on a change in capacitance, and the second bridge pattern BPR2 of the second sensor electrode SP2 capable of sensing a pressure by being arranged in a spiral configuration.

In the case where the second bridge pattern BRP2 is arranged in the spiral configuration, the second bridge pattern BRP2 (i.e., an electrode for sensing pressure) may be uniformly distributed over the entire surface of the touch panel 110 to provide stable and consistent sensing performance, regardless of a position where pressure is applied. In addition, the second bridge pattern BRP2 arranged in the spiral configuration may reduce differences in sensitivity which may occur between the central portion and the outer portion of the area AA (or an intersection region where the first sensor electrode SP1 and the second sensor electrode SP2 intersect).

As described above, the second bridge pattern BPR2 of the second sensor electrode SP2 included in the touch sensor may function not only a touch sensor but also a pressure sensor. Compared with the case where the pressure sensor is provided separately from the touch sensor, the manufacturing process of the touch panel 110 and the display device 100 including the touch panel 110 (see FIG. 1) is simplified and the manufacturing cost is reduced, thereby implementing the display device in a thin-profile configuration.

Although FIGS. 6 and 7 illustrate that the second bridge pattern BRP2 of the second sensor electrode SP2 extends in the spiral form, the disclosure is not limited thereto. For example, instead of the second bridge pattern BRP2, the first bridge pattern BRP1 of the first sensor electrode SP1 may extend in a spiral form.

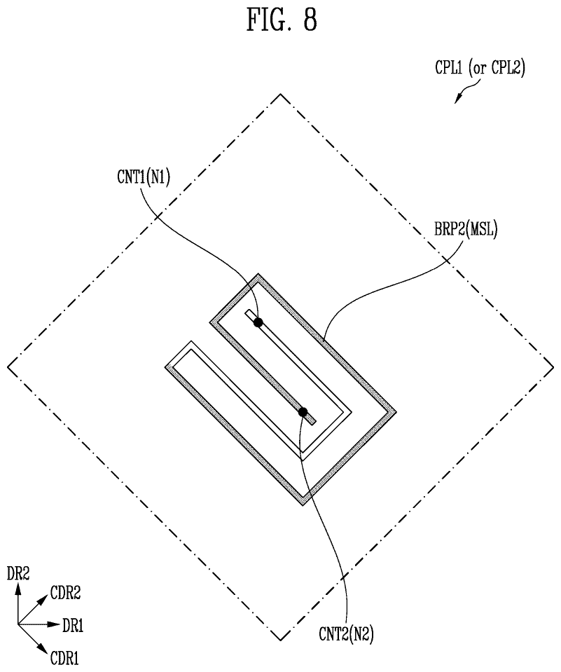

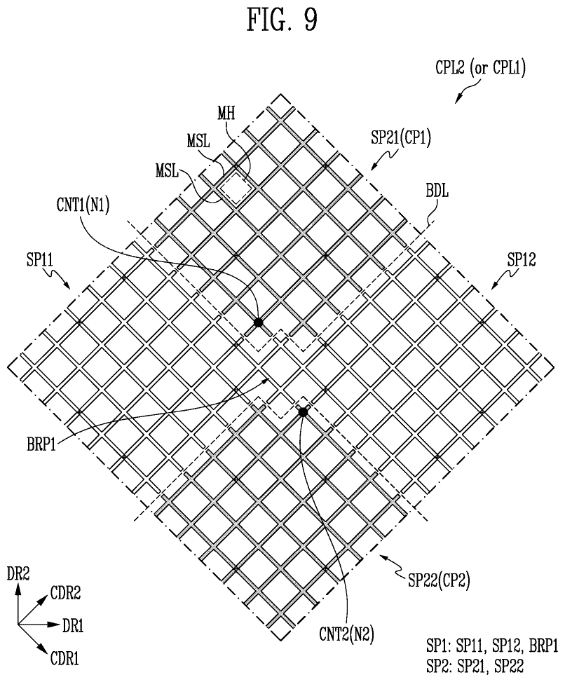

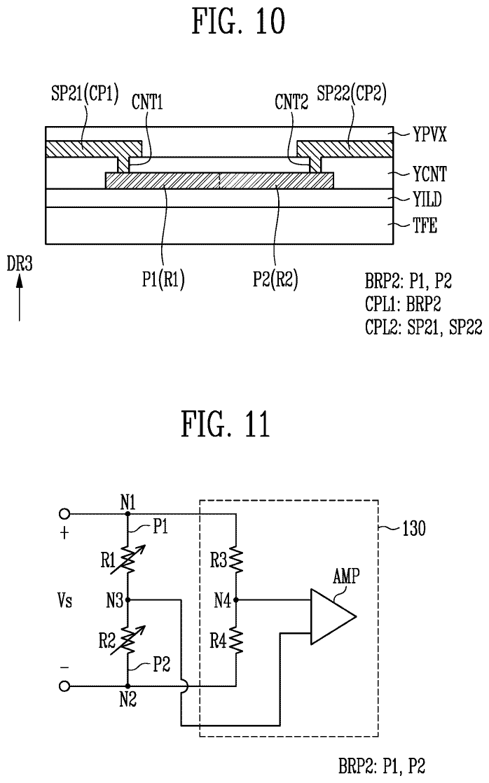

FIGS. 8 and 9 are enlarged plan views of an area AA of FIG. 4. In FIG. 8, conductive patterns of a first conductive layer CPL1 (hereinafter, first conductive patterns) are shown, and in FIG. 9, conductive patterns of a second conductive layer CPL2 (hereinafter, second conductive patterns) are shown. FIG. 10 is a cross-sectional view taken a the second bridge pattern BRP2 of FIG. 8.

Referring to FIGS. 8 to 10, the first conductive layer CPL1 includes the second bridge pattern BRP2, and the second conductive layer CPL2 may include the first sensor electrode SP1, the 21st sensor electrode SP21 (or the first sensor pattern CP1), and the 22nd sensor electrode SP22 (or the second sensor pattern CP2). However, the first and second conductive layers CPL1 and CPL2 are not limited to examples above. For example, the second conductive layer CPL2 may include the second bridge pattern BRP2, and the first conductive layer CPL1 may include the first sensor electrode SP1, the 21st sensor electrode SP21, and the 22nd sensor electrode SP22. The third sensing line SL3 as shown in FIG. 7 may be included in the first conductive layer CPL1 or the second conductive layer CPL2. For example, the third sensing line SL3 may be included in the first conductive layer CPL1 together with the second bridge pattern BRP2.

The first and second sensor electrodes SP1 and SP2 may include mesh lines MSL. Some of the mesh lines MSL may extend in the first diagonal direction CDR1, and other mesh lines MSL may extend in the second diagonal direction CDR2. The mesh lines MSL may intersect each other to define a mesh hole MH. The light-emitting element LD (see FIG. 5) of the display panel 120 may be exposed through the mesh hole MH, or light emitted from the light-emitting element LD may pass through the mesh hole MH.

In an embodiment, the second bridge pattern BRP2 of the second sensor electrode SP2 includes the mesh lines MSL, but the mesh hole MH may not be formed in the second bridge pattern BRP2. As a result, a resistance value of the second bridge pattern BRP2 (or resistance values of the first and second resistors R1 and R2 in FIG. 7) may increase, resulting in a greater resistance change rate for the same pressure and improvement of the sensing sensitivity. However, the disclosure is not limited thereto, and the second bridge pattern BRP2 may include the mesh hole MH. For example, the second bridge pattern BPR2 may have a line width corresponding to at least one mesh hole MH (or may include at least a pair of mesh lines MSL), and may be arranged in a spiral form. As the resistance value of the second bridge pattern BRP2 decreases, the pressure sensing may be less sensitive to external noise.

As shown in FIG. 9, each of the first sensor electrode SP1, the 21st sensor electrode SP21, and the 22nd sensor electrode SP22 includes a mesh pattern which is formed on the same layer as each other and distinguished from each other with respect to a boundary line BDL. In other words, the first sensor electrode SP1, the 21st sensor electrode SP21, and the 22nd sensor electrode SP22 may be differentiated as separate electrodes by patterning the mesh pattern along the boundary line BDL.

Referring to FIG. 10, the first conductive layer CPL1 is disposed between the first insulating layer YILD and the second insulating layer YCNT, and the second conductive layer CPL2 may be disposed between the second insulating layer YCNT and the third insulating layer YPVX. That is, the second insulating layer YCNT may be disposed between the first conductive layer CPL1 and the second conductive layer CPL2.

The 21st sensor electrode SP21 may be connected to the first end or the first portion P1 of the second bridge pattern BRP2 through the first contact hole CNT1, and the 22nd sensor electrode SP22 may be connected to the second end of the second portion P2 of the second bridge pattern BRP2 through the second contact hole CNT2.

The first and second conductive layers CPL1 and CPL2 may include a conductive material. The conductive material may include metals or alloys thereof, and may include gold (Au), silver (Ag), aluminum (Al), molybdenum (Mo), chromium (Cr), titanium (Ti), nickel (Ni), neodymium (Nd), copper (Cu), platinum (Pt), or the like. Furthermore, the first and second conductive layers CPL1 and CPL2 may include a transparent conductive material. The transparent conductive material may include silver nanowires (AgNW), indium tin oxide (ITO), indium zinc oxide (IZO), indium gallium zinc oxide (IGZO), in medium tin zinc oxide (ITZO), carbon nanotubes, graphene, or the like.

The first and second conductive layers CPL1 and CPL2 may have a single-layer structure or a multi-layer structure. For example, the first and second conductive layers CPL1 and CPL2 may have a triple-layer structure of titanium/aluminum/titanium.

In an embodiment, the first conductive layer CPL1 and the second conductive layer CPL2 may include the same material. For example, the second bridge pattern BRP2 may include the same material as the 21st sensor electrode SP21.

In an embodiment, the first conductive layer CPL1 and the second conductive layer CPL2 may include different materials from each other. For example, the second bridge pattern BRP2 and the 21st sensor electrode SP21 may include different materials from each other. For example, the first conductive layer CPL1 may include a material that shows a relatively large change in resistance caused by pressure, and the second conductive layer CPL2 may include a material having a relatively small change in resistance caused by pressure.

FIG. 11 is a diagram illustrating a touch panel driver 130 included in the display device 100 of FIG. 1. FIG. 11 schematically shows the touch panel driver 130 connected to the second bridge pattern BRP2 of FIGS. 6 and 7.

Referring to FIGS. 6, 7, and 11, the first portion P1 (or the first resistor R1) of the second bridge pattern BRP2 is electrically connected between a first node N1 and the third node N3, and the second portion P2 (or the second resistor R2) of the second bridge patterns BRP2 may be electrically connected between a second node N2 and the third node N3.

Each of the first node N1 and the second node N2 may be electrically connected to the touch panel driver 130. With reference to FIGS. 4 and 7, for example, the first node N1 may be electrically connected to the touch panel driver 130 through the 21st sensor electrode SP21 and the second sensing line SL2, and the second node N2 may be electrically connected to the touch panel driver 130 through the 22nd sensor electrode SP22 and the second sensing line SL2. A driving voltage Vs may be provided between the first node N1 and the second node N2. The third node N3 may be electrically connected to the touch panel driver 130 through the third sensing line SL3 in FIG. 7.

The touch panel driver 130 may include a third resistor R3, a fourth resistor R4, and an amplifier circuit AMP. According to an embodiment, the touch panel driver 130 may further include an analog-to-digital converter and a processor for detecting the output of the amplifier circuit AMP.

The third resistor R3 is electrically connected between the first node N1 and a fourth node N4, and the fourth resistor R4 may be electrically connected between the second node N2 and the fourth node N4. The third resistor R3 and the fourth resistor R4 may have invariable resistance values. The first resistor R1 and the second resistor R2 may be variable resistors. The first resistor R1, the second resistor R2, the third resistor R3, and the fourth resistor R4 may be included in the Wheatstone bridge circuit.

A first input terminal of the amplifier circuit AMP may be electrically connected to the third node N3, and a second input terminal of the amplifier circuit AMP may also be electrically connected to the fourth node N4.

The amplifier circuit AMP may be an amplifier and sense an electrical flow between the third node N3 and the fourth node N4. The amplifier circuit AMP may operate as a current sensing element or a voltage measuring element.

The amplifier circuit AMP may output a voltage proportional to a difference between voltage values provided to the first and second input terminals.

In the absence of a touch input, a multiplied value of the resistance of the first resistor R1 and the resistance of the fourth resistor R4 may be substantially equal to a multiplied value of the resistance of the second resistor R2 and the resistance of the third resistor R3. Thus, the voltage difference between the third node N3 and the fourth node N4 may be 0 V.

When a touch input is applied to the touch panel 110, the shape of the first resistor R1 or the second resistor R2 is deformed in response to the intensity of the touch. Due to the deformation of the shape of the first resistor R1 or the second resistor R2, the resistance value of the first resistor R1 or the second resistor R2 may change, and a voltage difference may occur between the third node N3 and the fourth node N4. When the voltage difference occurs between the third node N3 and the fourth node N4, the amplifier circuit AMP outputs a value other than 0 V, and the touch panel driver 130 may detect the intensity or the pressure of the touch by measuring a value output from the amplifier circuit AMP.

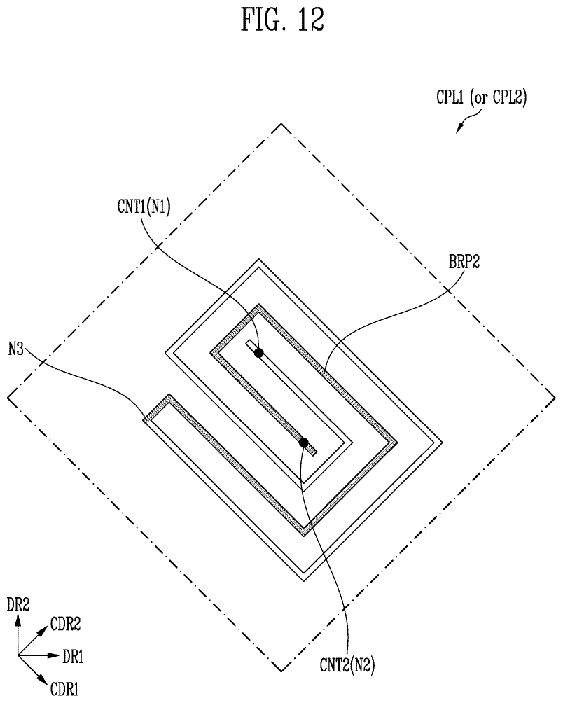

FIGS. 12, 13, and 14 are enlarged plan views of an area AA of FIG. 4. FIGS. 12, 13 and 14 show various embodiments of the second bridge pattern BRP2 of the first conductive layer CPL1.

Referring to FIGS. 6 to 8, 12, 13, and 14, except for the shape of the second bridge pattern BRP2, the second bridge pattern BRP2 of FIGS. 12, 13, and 14 is substantially the same as or similar to the second bridge pattern BRP2 of FIGS. 6 to 8. Thus, redundant descriptions thereof are omitted.

In an embodiment, as shown in FIG. 12, the second bridge pattern BRP2 may be wound three times while extending from the first contact hole CNT1 (or the first node N1) to the second contact hole CNT2 (or the second node N2) in a spiral form. The second bridge pattern BRP2 may have a double spiral structure, but the present disclosure is not limited thereto. According to an embodiment, the second bridge pattern BRP2 may be wound four or more times while extending in a spiral form.

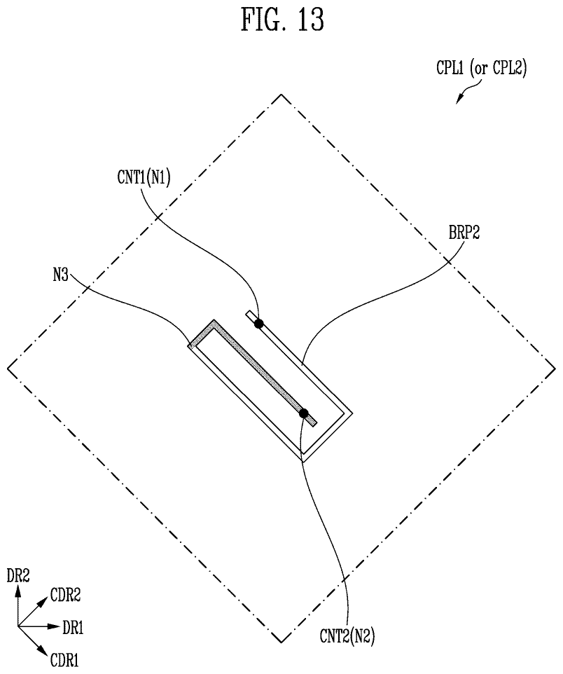

In an embodiment, as shown in FIG. 13, the second bridge pattern BRP2 may be wound one time while extending from the first contact hole CNT1 (or the first node N1) to the second contact hole CNT2 (or the second node N2) in a spiral form. The second bridge pattern BRP2 may have a single spiral structure, but the present disclosure is not limited thereto.

In an embodiment, as shown in FIG. 14, the second bridge pattern BRP2 may have a single spiral structure and extend from the first contact hole CNT1 (or the first node N1) to the second contact hole CNT2 (or the second node N2) in a spiral form with about three windings. Even in the case where the second bridge pattern BRP2 has a single spiral structure, the second bridge pattern BRP2 may be wound two times, four times or more.

Depending on design conditions such as pressure sensing sensitivity, sensitivity to external noise, size of a pressure sensing region, touch sensing sensitivity, etc., the shape (and size) of the second bridge pattern BRP2 may vary. For example, as a resistance value of the second bridge pattern BRP2 increases, the pressure sensing sensitivity may improve, the sensitivity to external noise may increase, and the touch sensing sensitivity may decrease. The pressure sensing region may refer to a unit sensing region covered by one second bridge pattern BRP2.

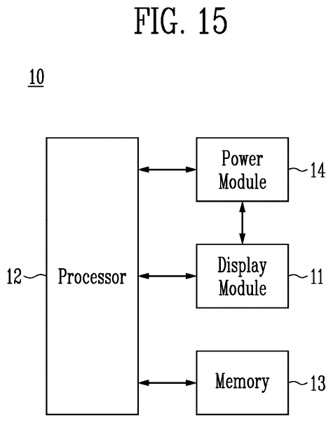

FIG. 15 is a block diagram of an electronic device 10 according to an embodiment.

Referring to FIG. 15, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. According to an embodiment, the processor 12 may include the touch panel driver 130 of FIG. 1, or may detect a touch input or intensity (or pressure) of the touch input based on a signal provided from the touch panel driver 130.

The memory 13 may store data and/or information used to operate the processor 12 or the display module 11. When the processor 12 executes an application stored in the memory 13, image data signals and/or input control signals may be transferred to the display module 11. The display module 11 may process the provided signals and display an image on a display screen.

The power module 14 (or a power supply) may include a power supply module, such as a power adapter or a battery device, and a power conversion module. The power conversion module converts power supplied from the power supply module and generates power to operate the electronic device 10.

At least one of the above-described components of the electronic device 10 may be included in the display device according to the above-described embodiments. In addition, in terms of functionality, some of the individual modules included in one module may be included in the display device and others may be provided separately from the display device. For example, the display module 11 is included in the display device, whereas the processor 12, the memory 13, and the power module 14 are not included in the display device 10 and are instead provided separately in the electronic device 10.

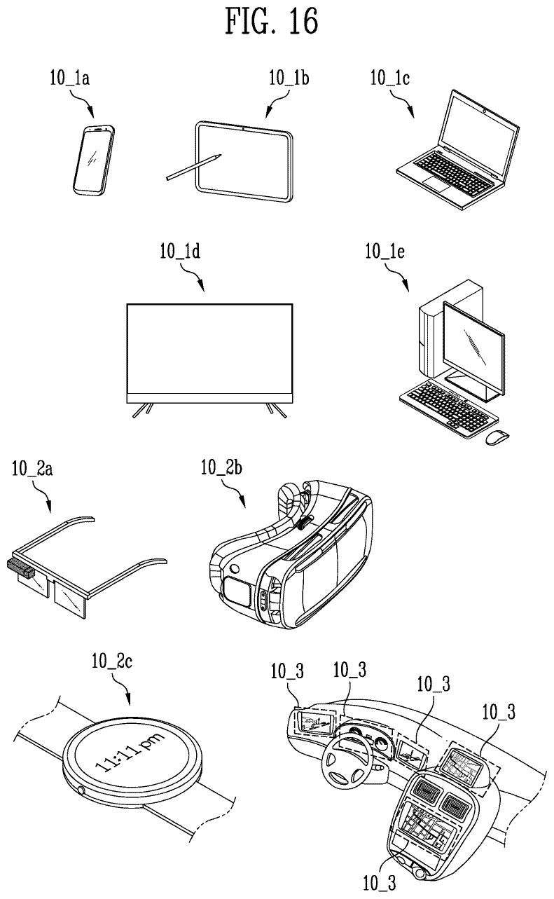

FIG. 16 shows schematic views of various embodiments of an electronic device.

Referring to FIG. 16, various types of electronic devices to which embodiments of the display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

In a sensing device, a display device, and an electronic device according to embodiments of the present disclosure, a second bridge pattern of a second sensor electrode for sensing a touch input may be arranged in a spiral shape and serve as a pressure sensor. Therefore, manufacturing processes may be simplified, and the sensing device, the display device, and the electronic device may have a pressure sensing function and be implemented in a thin-profile configuration.

Although the technical spirit of the disclosure has been described in detail in accordance with the above-described embodiments, it should be noted that the above-described embodiments are for the purpose of description and are not intended to limit the meaning and the scope of the disclosure described in claims. In addition, those skilled in the art may understand that various modifications are possible within the scope of the technical spirit of the disclosure as set forth in the following claims.

What is claimed is:

1. A sensing device comprising:
a first sensor electrode extending in a first direction; and
a second sensor electrode extending in a second direction and intersecting the first sensor electrode,
wherein the second sensor electrode comprises:
a first sensor pattern and a second sensor pattern, each of the first sensor pattern and the second sensor pattern not overlapping with the first sensor electrode; and
a bridge pattern partially overlapping with the first sensor electrode and connecting the first sensor pattern and the second sensor pattern, and
wherein the bridge pattern extends in a spiral form from a first end connected to the first sensor pattern to a second end connected to the second sensor pattern.

2. The sensing device of claim 1, wherein the bridge pattern has a double spiral structure.

3. The sensing device of claim 1, wherein the bridge pattern has a single spiral structure.

4. The sensing device of claim 1, wherein the first sensor electrode, the first sensor pattern, and the second sensor pattern are disposed in a first conductive layer,
wherein the bridge pattern is disposed in a second conductive layer, and
wherein an insulating layer is disposed between the first conductive layer and the second conductive layer.

5. The sensing device of claim 4, wherein each of the first sensor electrode and the second sensor electrode comprises mesh lines,
wherein the mesh lines form a mesh hole in each of the first sensor electrode and the second sensor electrode, and
wherein the mesh hole is not formed in the bridge pattern.

6. The sensing device of claim 1, wherein the first sensor electrode and the second sensor electrode sense a touch input based on a change in capacitance, and
wherein the bridge pattern has a resistance varying in response to pressure applied to the bridge pattern and senses the pressure.

7. The sensing device of claim 6, further comprising:
a first sensing line connected to the first sensor electrode;
a second sensing line connected to the second sensor electrode; and
a third sensing line connected to the bridge pattern,
wherein the bridge pattern comprises a first portion and a second portion separated with respect to a node connected to the third sensing line.

8. The sensing device of claim 7, wherein at least one of the first portion and the second portion has a U-shape in a plan view.

9. The sensing device of claim 1, wherein the bridge pattern and the first sensor pattern comprise a same material.

10. The sensing device of claim 1, wherein the bridge pattern and the first sensor pattern comprise different materials from each other.

11. A display device comprising:
a light-emitting element arranged on a base layer;
an encapsulation layer arranged on the light-emitting element; and
a sensor arranged on the encapsulation layer,
wherein the sensor comprises:
a first sensor electrode extending in a first direction; and
a second sensor electrode extending in a second direction and intersecting the first sensor electrode,
wherein the second sensor electrode comprises:
a first sensor pattern and a second sensor pattern, each of the first sensor pattern and the second sensor pattern not overlapping with the first sensor electrode; and
a bridge pattern partially overlapping with the first sensor electrode and connecting the first sensor pattern and the second sensor pattern, and
wherein the bridge pattern extends in a spiral form from a first end connected to the first sensor pattern to a second end connected to the second sensor pattern.

12. The display device of claim 11, wherein the first sensor electrode, the first sensor pattern, and the second sensor pattern are disposed in a first conductive layer, and
wherein the bridge pattern is located in a second conductive layer, and an insulating layer is disposed between the first conductive layer and the second conductive layer.

13. The display device of claim 12, wherein each of the first sensor electrode and the second sensor electrode comprises mesh lines,
wherein the mesh lines form a mesh hole in each of the first sensor electrode and the second sensor electrode, and
wherein the mesh hole corresponds to a light-emitting region of the light-emitting element, and the mesh hole is not formed in the bridge pattern.

14. The display device of claim 11, wherein the first sensor electrode and the second sensor electrode sense a touch input based on a change in capacitance, and
wherein the bridge pattern has a resistance varying in response to pressure applied to the bridge pattern and senses the pressure.

15. The display device of claim 14, wherein the sensor comprises:
a first sensing line connected to the first sensor electrode;
a second sensing line connected to the second sensor electrode; and
a third sensing line connected to the bridge pattern, and
wherein the bridge pattern comprises a first portion and a second portion separated with respect to a node connected to the third sensing line.

16. An electronic device, comprising:
a processor providing input image data;
a display module displaying an image based on the input image data; and
a power supply supplying power to the display module,
wherein the display module comprises:
a display panel including pixels; and
a sensor arranged on the display panel and sensing a touch input to the display module,
wherein the sensor comprises:
a first sensor electrode extending in a first direction; and
a second sensor electrode extending in a second direction and intersecting the first sensor electrode,
wherein the second sensor electrode comprises:
a first sensor pattern and a second sensor pattern, each of the first sensor pattern and the second sensor pattern not overlapping with the first sensor electrode; and
a bridge pattern partially overlapping with the first sensor electrode and connecting the first sensor pattern and the second sensor pattern,
wherein the bridge pattern extends in a spiral form from a first end connected to the first sensor pattern to a second end connected to the second sensor pattern, and
wherein the processor detects the touch input based on a change in capacitance, and detects a pressure of the touch input based upon a change in resistance of the bridge pattern in response to the pressure applied to the bridge pattern.

17. The electronic device of claim 16, wherein the first sensor electrode, the first sensor pattern, and the second sensor pattern are disposed in a first conductive layer, and
wherein the bridge pattern is disposed in a second conductive layer, and an insulating layer is disposed between the first conductive layer and the second conductive layer.

18. The electronic device of claim 17, wherein each of the first sensor electrode and the second sensor electrode comprises mesh lines,
wherein the mesh lines form a mesh hole in each of the first sensor electrode and the second sensor electrode, and
wherein the mesh hole corresponds to a light-emitting region of each of the pixels, and the mesh hole is not formed in the bridge pattern.

19. The electronic device of claim 16, wherein the sensor comprises:
a first sensing line connected to the first sensor electrode;
a second sensing line connected to the second sensor electrode; and
a third sensing line connected to the bridge pattern, and
wherein the bridge pattern comprises a first portion and a second portion separated with respect to a node connected to the third sensing line.

20. The electronic device of claim 19, wherein the processor detects the pressure based on a signal output through the third sensing line.
